(19) United States
(12) Patent Application Publication
(10) Pub. No.: US 2014/0250678 A1
(43) Pub. Date: Sep. 11, 2014

(54) SUBSTRATE TRANSPORT APPARATUS, ELECTRONIC DEVICE MANUFACTURING SYSTEM, AND ELECTRONIC DEVICE MANUFACTURING METHOD

(71) Applicant: CANON ANELVA CORPORATION, Kawasaki-shi (JP)

(72) Inventor: Kazuhito WATANABE, Tama-shi (JP)

(73) Assignee: CANON ANELVA CORPORATION, Kawasaki-shi (JP)

(21) Appl. No.: 14/284,985

(22) Filed: May 22, 2014

Related U.S. Application Data
(62) Division of application No. 13/276,667, filed on Oct. 19, 2011.

(30) Foreign Application Priority Data
Oct. 28, 2010 (JP) 2010-242619
Sep. 20, 2011 (JP) 2011-205215

(51) Int. Cl. H01L 21/677; H05K 13/00; B25J 11/00

(52) U.S. Cl. CPC H01L 21/677; B25J 11/0095; H05K 13/0015
USPC 29/592.1; 414/751.1; 414/222.01; 414/744.6

(57) ABSTRACT

A substrate transport apparatus comprises a substrate holder capable of holding a substrate, a link unit which extends/retracts the substrate holder, a driving unit which generates a driving force to operate the link unit, a guide bar provided to one of the substrate holder and the link unit; and a support unit which is provided to the other of the substrate holder and the link unit, and slidably supports the guide bar when the substrate holder moves by the operation of the link unit.

This is a Division of application Ser. No. 13/276,667 filed Oct. 19, 2011, which claims the benefit of Japanese Application No. 2011-205215 filed on Sep. 20, 2011 and Japanese Application No. 2010-242619 filed on Oct. 28, 2010. The disclosures of the prior applications are hereby incorporated by reference herein in their entirety.

### BACKGROUND OF THE INVENTION

1. Field of the Invention

The present invention relates to a substrate transport apparatus, an electronic device manufacturing system, and an electronic device manufacturing method.

2. Description of the Related Art

FIGS. 13A and 13B schematically show the configuration of a conventional substrate transport apparatus. Referring to FIGS. 13A and 13B, a conventional substrate transport apparatus 500 includes a first substrate holding device 500A and second substrate holding device 500B capable of holding a substrate W. A first driving arm 502A and second driving arm 502B serving as members which constitute the first substrate holding device 500A and second substrate holding device 500B, respectively, are fixed on the drive shafts of first and second driving units 501A and 501B, respectively, so that they are vertically stacked on each other. The first driving arm 502A and second driving arm 502B are shared by the first substrate holding device 500A and second substrate holding device 500B, as will be described later.

The first substrate holding device 500A includes the first driving arm 502A, a pair of first intermediate arms 503AR and 503AL, and a first substrate holder 505A. The first driving arm 502A is rotatably connected to the first driving unit 501A. The right, first intermediate arm 503AR is rotatably connected to a right end 502A1 of the first driving arm 502A, and the left, first intermediate arm 503AL is rotatably connected to a left end 502B2 of the second driving arm 502B. The first substrate holder 505A is connected to the pair of first intermediate arms 503AR and 503AL.

Similarly, the second substrate holding device 500B includes the second driving arm 502B, a pair of second intermediate arms 503BR and 503BL, and a second substrate holder 505B. The second driving arm 502B is rotatably connected to the second driving unit 501B. The right, second intermediate arm 503BR is rotatably connected to a right end 502B1 of the second driving arm 502B, and the left, second intermediate arm 503BL is rotatably connected to a left end 502A2 of the first driving arm 502A. The second driving arm 502B is connected to the pair of second intermediate arms 503BR and 503BL.

During revolution as shown in FIG. 13A, the first and second driving arms 502A and 502B, first and second intermediate arms 503AR, 503AL, 503BR, and 503BL, first and second substrate holders 505A and 505B are stacked on each other vertically (in the Z direction). Then, the substrate transport apparatus 500 assumes a contraction state in which the first and second substrate holding devices 500A and 500B look as if they were integrated, when viewed in a top view, as shown in FIG. 13A.

On the other hand, during extension/contraction shown in FIG. 13B, the drive shafts of the first and second driving units 501A and 501B are rotationally driven in opposite directions from the contraction state shown in FIG. 13A, thereby allowing the first substrate holder 505A and second substrate holder 505B to extend or retract in opposite directions.

As shown in FIGS. 14A and 14B, each of the first substrate holder 505A and second substrate holder 505B is connected to two portions: the first intermediate arms 503AR and 503AL or the second intermediate arms 503BR and 503BL, respectively. The ends of the pair of intermediate arms 503AR and 503AL or 503BR and 503BL are connected to each other in an S shape using a belt 507A or 507B via a roller 506A or 506B (FIG. 14A), or mesh with each other using a gear 508A or 508B (FIG. 14B) (see, for example, Japanese Patent Laid-Open No. 11-514303 and Japanese Patent Laid-Open No. 11-207666). In this way, the change in angle θ′ of the pair of intermediate arms is maintained constant with reference to the extension/contraction direction (Y direction) for each of the substrate holders 505A and 505B, thereby ensuring their rectilinear movement characteristics.

Unfortunately, the above-mentioned conventional configuration poses a problem resulting from oscillation of the substrate holders while they extend/contract. That is, it is difficult for the configuration which uses belts, as shown in FIG. 14A, to ensure a given operation reproducibility (positioning reproducibility) because the substrate holders oscillate with respect to the intermediate arms due to elastic deformation of the belts. Also, due to the elasticity of the belts, the behaviors of the substrate holders are not quickly fed back, thus degrading the control response characteristics degrade, and imposing a limit beyond which it is no longer possible to improve the servo rigidity.

Also, the configuration which uses gears, as shown in FIG. 14B, generates backlash when the gears mesh with each other, and this produces an effect equivalent to that produced by the cushioning properties of belts, thus posing the same problem as mentioned above.

Furthermore, when a substrate is transported into a chamber maintained at a high temperature, the configurations as shown in FIGS. 14A and 14B pose a problem that the substrate holders receive heat from the chamber so that the belts or gears thermally expand, thus degrading the positioning reproducibility.

### SUMMARY OF THE INVENTION

The present invention has been made in consideration of the aforementioned problems, and realizes a substrate transport apparatus capable of improving the positioning reproducibility, the control response characteristics, and the servo rigidity.

The present invention also realizes a substrate transport apparatus which can ensure a given positioning reproducibility even when a substrate is transported into a chamber maintained at a high temperature.

In order to solve the aforementioned problems, the present invention provides a substrate transport apparatus comprising: a substrate holder capable of holding a substrate; a link unit which extends/retracts the substrate holder; a driving unit which generates a driving force to operate the link unit; a guide bar provided to one of the substrate holder and the link unit; and a support unit which is provided to the other of the substrate holder and the link unit, and slidably supports the guide bar when the substrate holder moves by the operation of the link unit.

In order to solve the aforementioned problems, the present invention provides a substrate transport apparatus comprising: a first substrate holder and a second substrate holder capable of holding a substrate; a first link unit and a second link unit which extend/retract the first substrate holder and the second substrate holder, respectively; a first driving unit and a second driving unit which generate driving forces to operate the first link unit and the second link unit, respectively; a first guide bar provided to one of the first substrate holder and the first link unit; a second guide bar provided to one of the second substrate holder and the second link unit; a first support unit which is provided to the other of the first substrate holder and the first link unit, and slidably supports the first guide bar when the first substrate holder moves by the operation of the first link unit; and a second support unit which is provided to the other of the second substrate holder and the second link unit, and slidably supports the second guide bar when the second substrate holder moves by the operation of the second link unit.

In order to solve the aforementioned problems, the present invention provides an electronic device manufacturing system comprising: the substrate transport apparatus defined above; and at least one process apparatus which executes a device manufacturing process for a substrate transported by the substrate transport apparatus.

According to the present invention, a substrate transport apparatus capable of ensuring a given positioning reproducibility and improving the control response characteristics and the servo rigidity is realized. In addition, since a given positioning reproducibility can be ensured, the stability of a rectilinear movement operation also improves.

Also, since an increase in rigidity of a robot, a speedup of a response to feedback control, and a reduction in temporal change of components can be attained, stabilization and an improvement in reliability of a substrate transport system can be achieved, leading to an improvement in productivity.

Moreover, since the need for operations associated with belt adjustment and gear maintenance can be obviated, the operation efficiency can be improved.

Further features of the present invention will become apparent from the following description of exemplary embodiments with reference to the attached drawings.

### BRIEF DESCRIPTION OF THE DRAWINGS

FIG. 1A is a plan view showing the state of a substrate transport apparatus in the first embodiment according to the present invention during revolution;

FIG. 1B is a plan view showing the state of the substrate transport apparatus in the first embodiment according to the present invention during extension/contraction;

FIG. 2A is an external view of the substrate transport apparatus in the first embodiment during revolution;

FIG. 2B is a left side view of the substrate transport apparatus in the first embodiment during revolution;

FIG. 2C is a rear view of the substrate transport apparatus in the first embodiment during revolution;

FIG. 3A is an external view of the substrate transport apparatus in the first embodiment during extension/contraction;

FIG. 3B is a left side view of the substrate transport apparatus in the first embodiment during extension/contraction;

FIG. 3C is a rear view of the substrate transport apparatus in the first embodiment during extension/contraction;

FIG. 4A is an external view of the substrate transport apparatus in the first embodiment during extension/contraction;

FIG. 4B is a left side view of the substrate transport apparatus in the first embodiment during extension/contraction;

FIG. 4C is a rear view of the substrate transport apparatus in the first embodiment during extension/contraction;

FIG. 5A is an external view of a substrate transport apparatus in the second embodiment according to the present invention during revolution;

FIG. 5B is a left side view of the substrate transport apparatus in the second embodiment according to the present invention during revolution;

FIG. 5C is a rear view of the substrate transport apparatus in the second embodiment according to the present invention during revolution;

FIG. 6A is an external view of the substrate transport apparatus in the second embodiment according to the present invention during extension/contraction;

FIG. 6B is a left side view of the substrate transport apparatus in the second embodiment according to the present invention during extension/contraction;

FIG. 6C is a rear view of the substrate transport apparatus in the second embodiment according to the present invention during extension/contraction;

FIG. 7A is an external view of the substrate transport apparatus in the second embodiment according to the present invention during extension/contraction;

FIG. 7B is a left side view of the substrate transport apparatus in the second embodiment according to the present invention during extension/contraction;

FIG. 7C is a rear view of the substrate transport apparatus in the second embodiment according to the present invention during extension/contraction;

FIG. 8 is an enlarged view of a portion P1 in FIG. 3, which shows details of a guide mechanism in a first example;

FIG. 9A is an enlarged view of the portion P1 in FIG. 3, which shows details of a guide mechanism in a second example;

FIG. 9B is a sectional view taken along a line I-I in FIG. 9A;

FIG. 10A is an enlarged view of the portion P1 in FIG. 3, which shows details of a guide mechanism in a third example;

FIG. 10B is a rear view of the guide mechanism in the third example when viewed from a direction indicated by an arrow P2 in FIG. 10A;

FIG. 11 is a block diagram showing the control block configuration of the substrate transport apparatus in an embodiment according to the present invention;

FIG. 12 is a diagram illustrating an electronic device manufacturing system in the embodiment according to the present invention;

FIG. 13A is a plan view showing the state of a conventional substrate transport apparatus during revolution;

FIG. 13B is a plan view showing the state of the conventional substrate transport apparatus during extension/contraction;

FIGS. 14A and 14B are views showing details of a portion P′ in FIG. 13B;

FIG. 15A is a plan view of the vicinity of substrate holders of a substrate transport apparatus in the third embodiment during revolution;

FIG. 15B is a sectional view taken along a line I-I in FIG. 15A;

FIG. 15C is a sectional view taken along a line II-II in FIG. 15A; and

FIG. 16 is a plan view of the vicinity of the substrate holders of the substrate transport apparatus in the third embodiment during extension/contraction.

### DESCRIPTION OF THE EMBODIMENTS

Exemplary embodiments of the present invention will be described in detail below with reference to the accompanying drawings. However, constituent elements described in these embodiments merely give examples, so the technical scope of the present invention is determined by the scope of claims and is not limited by the following individual embodiments.

### First Embodiment

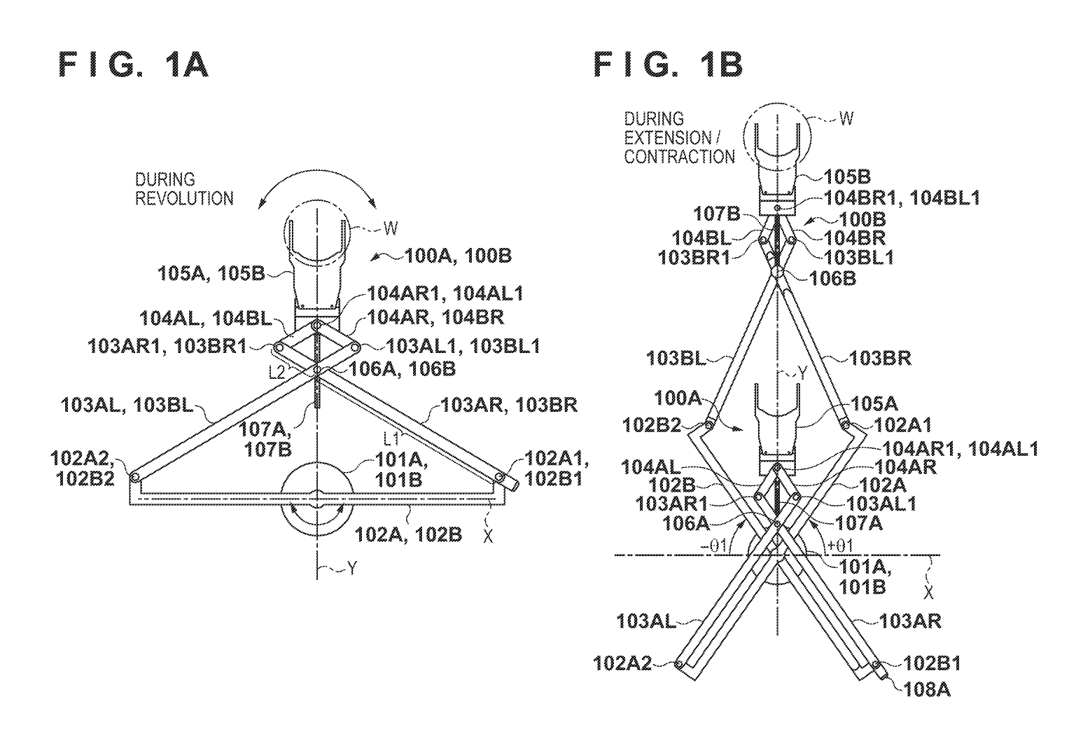

A substrate transport apparatus in the first embodiment according to the present invention will be described first with reference to FIGS. 1A to 4C. Referring to FIG. 1A, a substrate transport apparatus 100 in this embodiment includes a first substrate holding device 100A and second substrate holding device 100B capable of holding a substrate W. The substrate W is, for example, a wafer having a diameter of about 300 mm. Note that in each of the following embodiments, a suffix “A” is added to reference numerals denoting elements which constitute the first substrate holding device 100A, and a suffix “B” is added to reference numerals denoting elements which constitute the second substrate holding device 100B.

The first substrate holding device 100A includes a first driving arm 102A rotatably connected to a first driving unit 101A, and the second substrate holding device 100B includes a second driving arm 102B rotatably connected to a second driving unit 101B. The first driving arm 102A and second driving arm 102B are fixed on the drive shafts of the first and second driving units 101A and 101B, respectively, so that they are stacked on each other vertically (in the Z direction). The first driving arm 102A and second driving arm 102B are shared by the first substrate holding device 100A and second substrate holding device 100B, as will be described later.

The drive shaft of the first driving unit 101A has a columnar shape, and that of the second driving unit 101B has a hollow cylindrical shape. The drive shaft of the first driving unit 101A is disposed in the hollow space of the drive shaft of the second driving unit 101B so that the drive shafts of the first driving unit 101A and second driving unit 101B can be rotationally driven coaxially, concentrically, and independently.

The first substrate holding device 100A includes the first driving arm 102A, a pair of first intermediate arms 103AR and 103AL, a pair of first terminal arms 104AR and 104AL, and a first substrate holder 105A, which exemplify a first link unit. The first intermediate arms 103AR and 103AL and the first terminal arms 104AR and 104AL have equal distances between fulcrums.

The first driving arm 102A is rotatably connected to the first driving unit 101A. The first intermediate arms 103AR and 103AL are rotatably connected to a right end 102B1 of the second driving arm 102B and a left end 102A2 of the first driving arm 102A, respectively. The first terminal arms 104AR and 104AL are rotatably connected to the other end 103AL1 of the first intermediate arm 103AL and the other end 103AR1 of the first intermediate arm 103AR, respectively. The first substrate holder 105A is connected to the other end of each of the pair of first terminal arms 104AR and 104AL.

The pair of first intermediate arms 103AR and 103AL are rotatably connected to each other at a first cross-connection point 106A so that a portion on the side of the other end of the first intermediate arm 103AR, which is opposite to its one end connected to the second driving arm 102B, and a portion on the side of the other end of the first intermediate arm 103AL, which is opposite to its one end connected to the first driving arm 102A, intersect with each other while being vertically stacked on each other. The first cross-connection point 106A is set at a position at which the length L2 from the other end of each of the first intermediate arms 103AR and 103AL is shorter than the length L1 from one end of the same one (for example, L1:L2=5:1). The length of each arm and the ratio between the lengths divided by the cross-connection point are arbitrarily determined for each individual apparatus in accordance with the distances by which the first and second substrate holders 105A and 105B extend or retract (to be described later).

One end of each of the pair of first terminal arms 104AR and 104AL is connected to the corresponding one of the other end 103AR1 of the first intermediate arm 103AR and the other end 103AL1 of the first intermediate arm 103AL. Also, the other end 104AR1 of the first terminal arm 104AR and the other end 104AL1 of the first terminal arm 104AL in the pair of first terminal arms 104AR and 104AL are rotatably connected to the first substrate holder 105A while being vertically stacked on each other. The length of the first terminal arms 104AR and 104AL is nearly equal to the length L2 from the first cross-connection point 106A between the first intermediate arms 103AR and 103AL to the other end 103AR1 and the other end 103AL1.

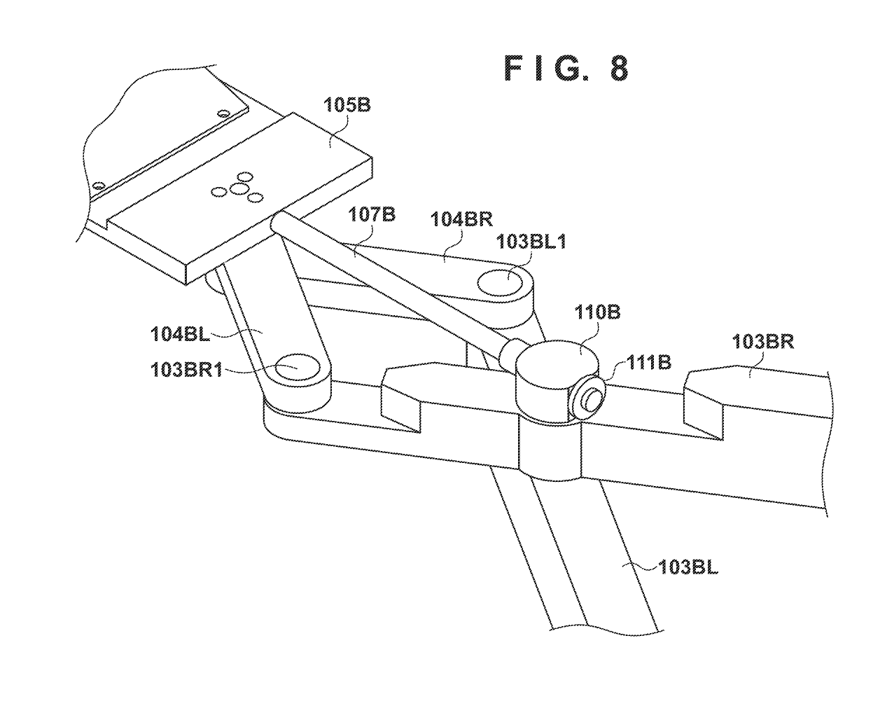

Moreover, a first guide bar 107A is provided at the rear end of the first substrate holder 105A to extend toward the first cross-connection point 106A (in the Y direction). The other end of the first guide bar 107A, which is opposite to its one end connected to the first substrate holder 105A, is slidably supported by a guide mechanism at the first cross-connection point 106A, as will be described with reference to FIGS. 8 to 10B. Thus, oscillation of the first substrate holder 105A is suppressed in extending/contracting the first substrate holding device 100A.

The second substrate holding device 100B has almost the same configuration as the above-mentioned first substrate holding device 100A. That is, the second substrate holding device 100B includes the second driving arm 102B, a pair of second intermediate arms 103BR and 103BL, a pair of second terminal arms 104BR and 104BL, and a second substrate holder 105B, which exemplify a second link unit. The second intermediate arms 103BR and 103BL and the second terminal arms 104BR and 104BL have equal distances between fulcrums.

The second driving arm 102B is rotatably connected to the second driving unit 101B. The second intermediate arms 103BR and 103BL are rotatably connected to a right end 102A1 of the first driving arm 102A and a left end 102B2 of the second driving arm 102B, respectively. The second terminal arms 104BR and 104BL are rotatably connected to the other end 103BL1 of the second intermediate arm 103BL and the other end 103BR1 of the second intermediate arm 103BR, respectively. The second substrate holder 105B is connected to the other end 104BR1 of the second terminal arm 104BR and the other end 103BL1 of the second terminal arm 104BL in the pair of second terminal arms 104BR and 104BL.

Note that the first intermediate arm 103AR is connected to the right end 102B1 of the second driving arm 102B at a position above the right end 102A1 of the first driving arm 102A via a connecting member 108A. Interposing the connecting member 108A in this way makes it possible to form a space in the Z direction between the second driving arm 102B and the first intermediate arm 103AR so that the first driving arm 102A and the second intermediate arm 103BR connected to it can be disposed in this space while being stacked on each other. Thus, the substrate transport apparatus in a contraction state can be compactly accommodated in a three-dimensional space.

Other configurations are the same as in the first substrate holding device 100A.

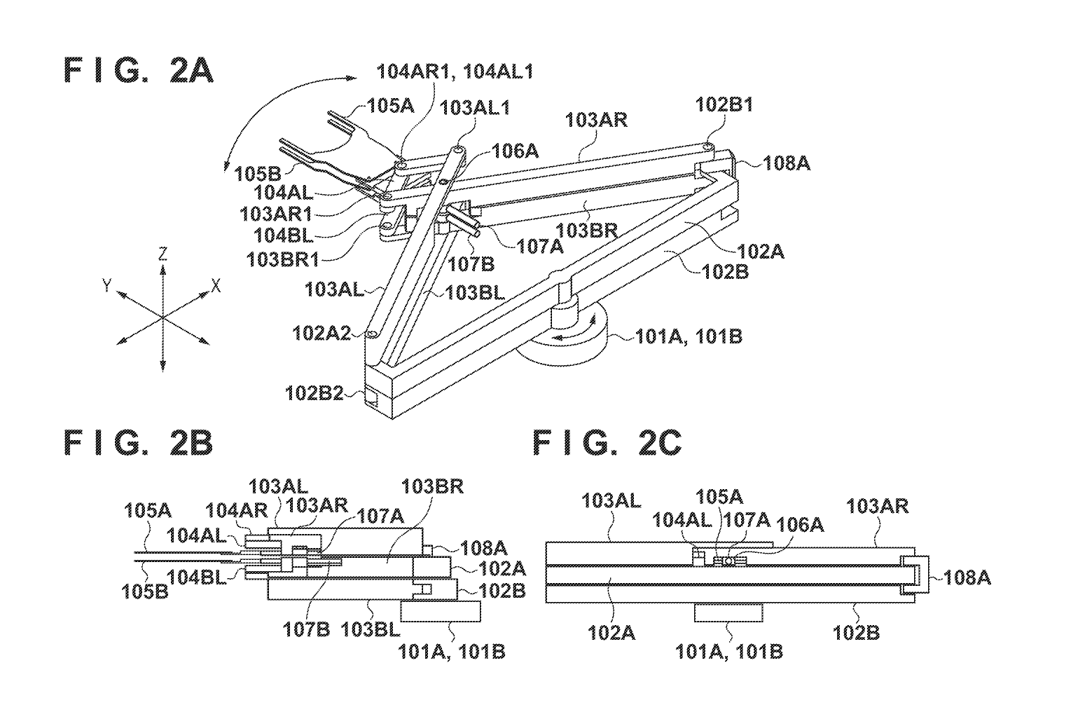

During revolution shown in FIGS. 1A and 2A to 2C, when viewed in a top view, as shown in FIGS. 1A and 2A, the first driving arm 102A and second driving arm 102B, the first intermediate arm 103AR or 103AL and second intermediate arm 103BR or 103BL, the first terminal arm 104AR or 104AL and second terminal arm 104BR or 104BL, the first substrate holder 105A and second substrate holder 105B, and the first cross-connection point 106A and second cross-connection point 106B are vertically stacked on each other, so the substrate transport apparatus 100 assumes a contraction state in which the first substrate holding device 100A and second substrate holding device 100B look as if they were integrated, as shown in FIGS. 1A and 2A.

In this contraction state, the drive shafts of the first and second driving units 101A and 101B are rotationally driven in the same direction. Thus, the first substrate holder 105A and second substrate holder 105B integrally revolve by a swing operation using the drive shafts of the first and second driving units 101A and 101B as common shafts.

On the other hand, during extension/contraction shown in FIGS. 1B and 3A to 4C, the drive shafts of the first and second driving units 101A and 101B are rotationally driven in opposite directions from the contraction state shown in FIGS. 2A to 2C. Thus, the first substrate holder 105A and second substrate holder 105B extend/retract so as to extend/contract in opposite Y directions.

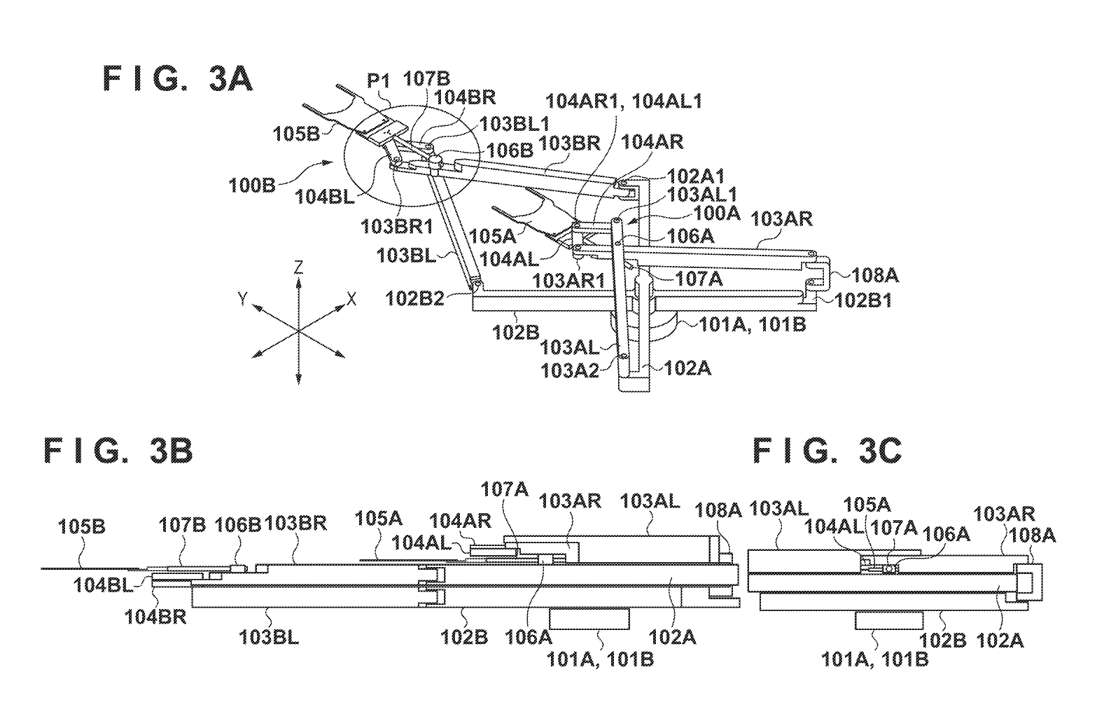

For example, as shown in FIGS. 1B and 3A to 3C, upon defining the counterclockwise direction as the positive direction, the first driving arm 102A is rotationally driven through +θ1 counterclockwise, and the second driving arm 102B is rotationally driven through −θ1 clockwise from the state shown in FIG. 1A. Then, the first cross-connection point 106A moves backward by an interlock among the first driving arm 102A of the first substrate holding device 100A (the second driving arm 102B of the second substrate holding device 100B), the first intermediate arms 103AR and 103AL, and the first terminal arms 104AR and 104AL. Simultaneously, the second cross-connection point 106B moves forward by an interlock among the second driving arm 102B of the second substrate holding device 100B, the second intermediate arms 103BR and 103BL, and the second terminal arms 104BR and 104BL. Thus, the first substrate holder 105A retracts, whereas the second substrate holder 105B extends.

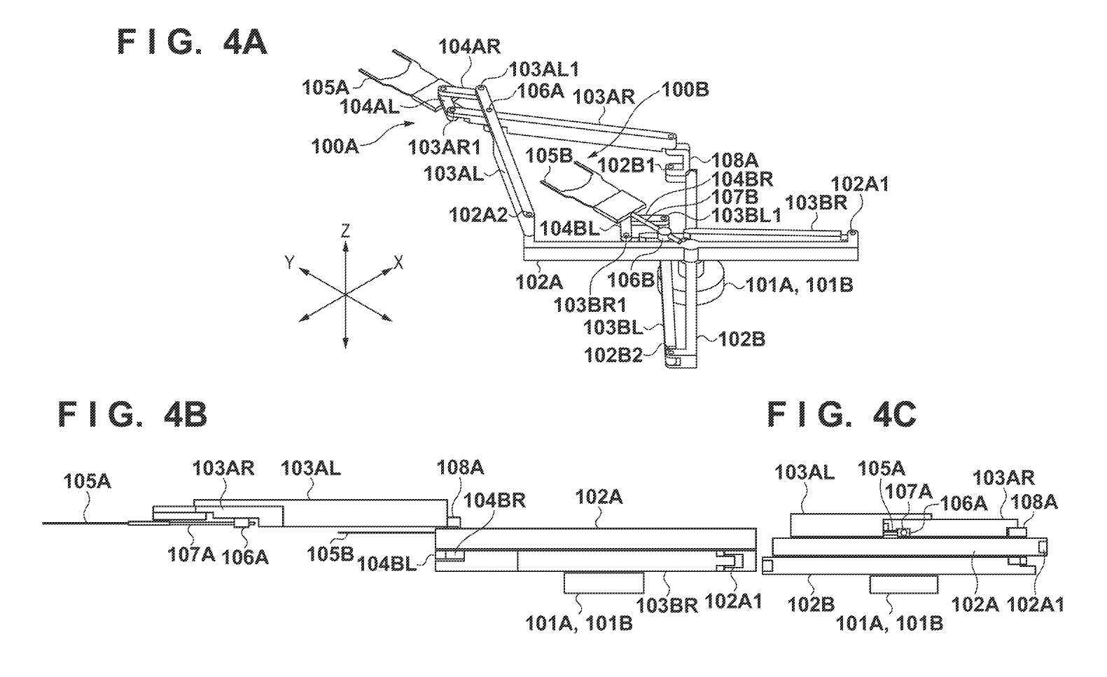

In contrast, as shown in FIGS. 1B and 4A to 4C, the first driving arm 102A is rotationally driven through −θ1 clockwise, and the second driving arm 102B is rotationally driven through +θ1 counterclockwise from the state shown in FIG. 1A. Then, the first cross-connection point 106A moves forward by an interlock among the first driving arm 102A of the first substrate holding device 100A, the first intermediate arms 103AR and 103AL, and the first terminal arms 104AR and 104AL. Simultaneously, the second cross-connection point 106B moves backward by an interlock among the second driving arm 102B of the second substrate holding device 100B, the second intermediate arms 103BR and 103BL, and the second terminal arms 104BR and 104BL. Thus, the first substrate holder 105A extends, whereas the second substrate holder 105B retracts.

### Second Embodiment

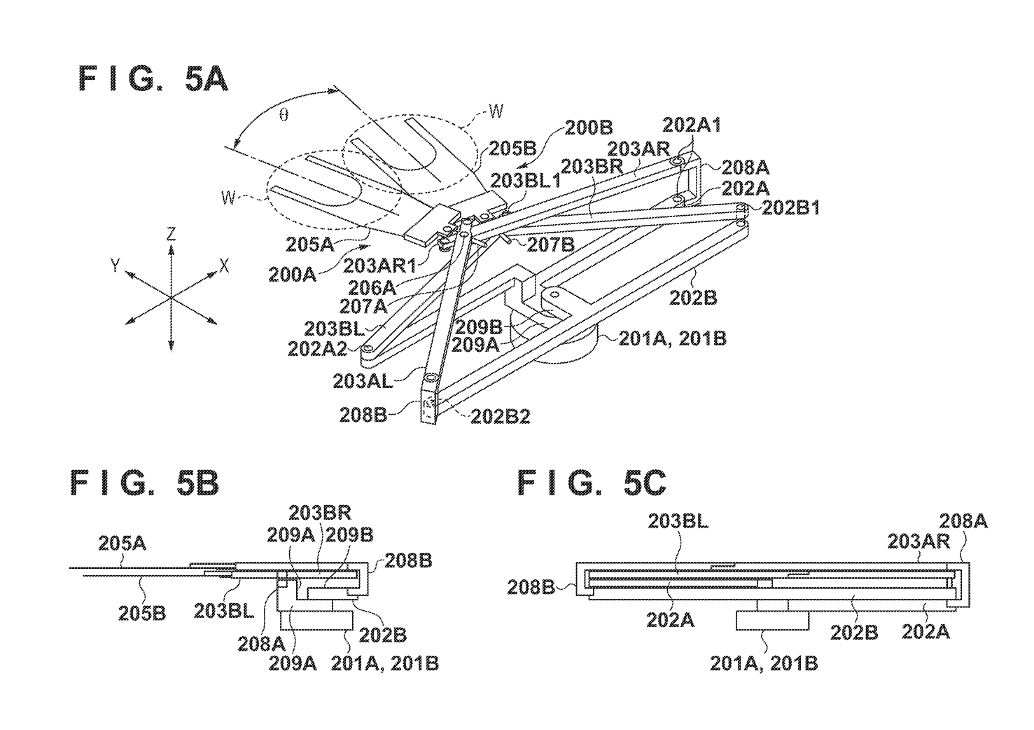

A substrate transport apparatus in the second embodiment according to the present invention will be described next with reference to FIGS. 5A to 7C.

A substrate transport apparatus 200 in this embodiment is different from the substrate transport apparatus 100 in the first embodiment in that in the former a first driving arm 202A and second driving arm 202B are disposed to have an offset between them in the Y direction (extension/contraction direction) in advance, whereas in the latter the first and second driving arms 102A and 102B are stacked on each other in a contraction state.

That is, as shown in FIGS. 5A to 5C, the first driving arm 202A is rotatably connected to a first driving unit 201A via a first offset arm 209A extending in the retraction direction along the extension/contraction direction from its center. The second driving arm 202B is rotatably connected to a second driving unit 201B via a second offset arm 209B extending in the extension direction along the extension/contraction direction from its center. The first driving arm 202A is formed such that its left portion is bent to a level higher than its right portion with respect to the first offset arm 209A.

A first substrate holding device 200A includes the first driving arm 202A (second driving arm 202B), a pair of first intermediate arms 203AR and 203AL, a pair of first terminal arms 204AR and 204AL, and a first substrate holder 205A, which exemplify a first link unit.

The first driving arm 202A is rotatably connected to the first driving unit 201A. The first intermediate arms 203AR and 203AL are rotatably connected to a right end 202A1 of the first driving arm 202A and a left end 202B2 of the second driving arm 202B, respectively. The first terminal arms 204AR and 204AL are rotatably connected to the other end 203AL1 of the first intermediate arm 203AL and the other end 203AR1 of the first intermediate arm 203AR, respectively. The first substrate holder 205A is connected to the other end of each of the pair of first terminal arms 204AR and 204AL.

Note that the first intermediate arm 203AR is connected to a position above the right end 202A1 of the first driving arm 202A via a connecting member 208A. Also, the first intermediate arm 203AL is connected to a position above the left end 202B2 of the second driving arm 202B via a connecting member 208B. Interposing the connecting member 208A in this way makes it possible to form a space in the Z direction between the right, first driving arm 202A and the first intermediate arm 203AR so that this space can serve as an operation space for the second driving arm 202B and a second intermediate arm 203BR. Also, interposing the connecting member 208B makes it possible to form a space in the Z direction between the left, second driving arm 202B and the first intermediate arm 203AL so that this space can serve as an operation space for the left, first driving arm 202A and a second intermediate arm 203BL.

Thus, the substrate transport apparatus in a contraction state can be compactly accommodated in a three-dimensional space.

A second substrate holding device 200B includes the second driving arm 202B (first driving arm 202A), the pair of second intermediate arms 203BR and 203BL, a pair of second terminal arms 204BR and 204BL, and a second substrate holder 205B, which exemplify a second link unit.

The second driving arm 202B is rotatably connected to the second driving unit 201B. The second intermediate arms 203BR and 203BL are rotatably connected to a right end 202B1 of the second driving arm 202B and a left end 202A2 of the first driving arm 202A, respectively. The second terminal arms 204BR and 204BL are rotatably connected to the other end 203BL1 of the second intermediate arm 203BL and the other end 203BR1 of the second intermediate arm 203BR, respectively. The second substrate holder 205B is connected to the other end of each of the pair of second terminal arms 204BR and 204BL.

Other configurations are the same as in the first embodiment. Hence, members having the same configurations and functions as in the first embodiment are denoted by reference numerals obtained by changing the hundreds digit of reference numerals in the first embodiment from 1 to 2, and a description thereof will not be given.

Also, the length of the first and second intermediate arms 203AR, 203AL, 203BR, and 203AL, the positions of first and second cross-connection points 206A and 206B, and the length of the first and second terminal arms 204AR, 204AL, 204BR, and 204AL are changed as needed.

During revolution shown in FIGS. 5A to 5C, the first driving arm 202A and second driving arm 202B extend parallel to each other in the X direction with a predetermined spacing between them in the Y direction. In this contraction state, the drive shafts of the first and second driving units 201A and 201B are rotationally driven in the same direction, so the first substrate holder 205A and second substrate holder 205B revolve by a swing operation using the drive shafts of the first and second driving units 201A and 201B as common shafts.

Note that in this contraction state, the first and second substrate holders 205A and 205B are shifted by a predetermined angle θ with respect to the Y direction without overlap.

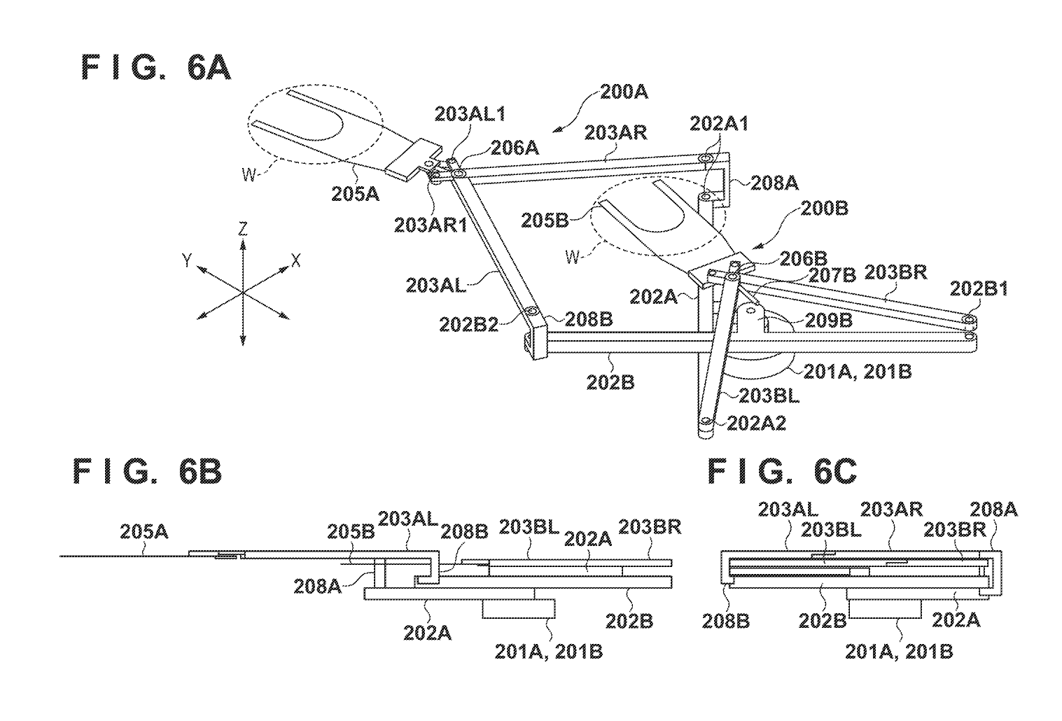

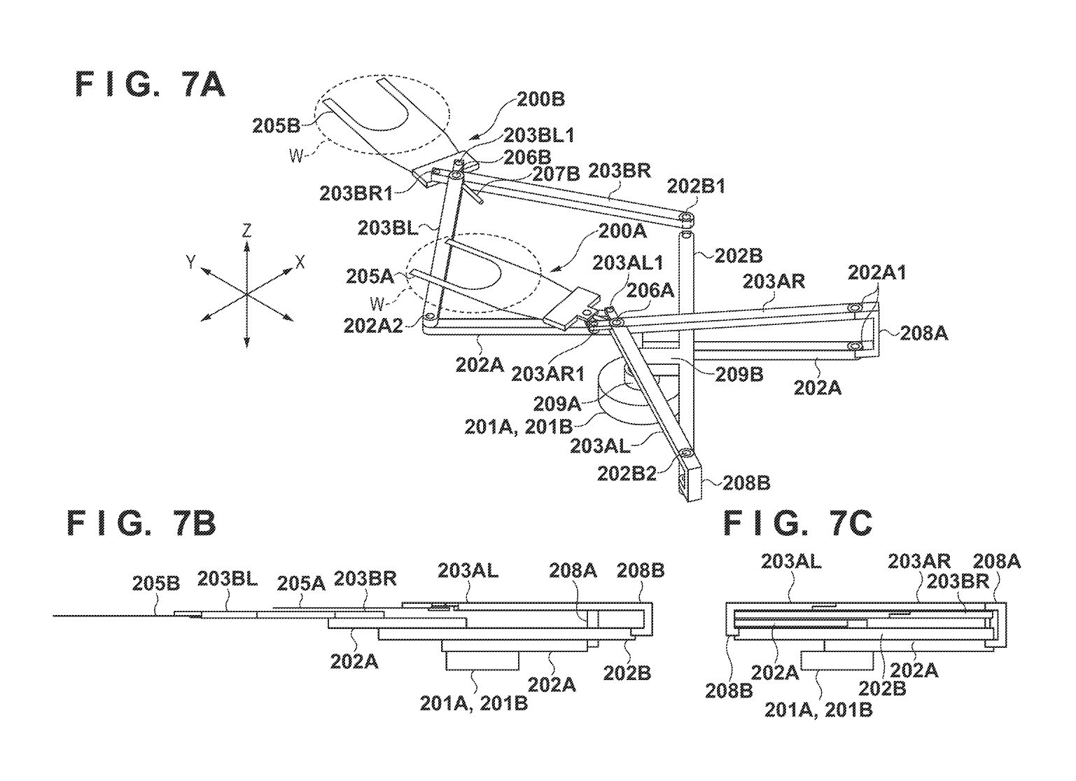

On the other hand, during extension/contraction shown in FIGS. 6A to 7C, the drive shafts of the first and second driving units 201A and 201B are rotationally driven in opposite directions from the contraction state shown in FIGS. 5A to 5C, so the first substrate holder 205A and second substrate holder 205B extend/retract so as to extend/contract in opposite directions.

For example, as shown in FIGS. 6A to 6C, upon defining the counterclockwise direction as the positive direction, the first driving arm 202A is rotationally driven thorough a predetermined angle θ counterclockwise, and the second driving arm 202B is rotationally driven through the predetermined angle θ clockwise. Then, the first cross-connection point 206A moves forward by an interlock among the first driving arm 202A of the first substrate holding device 200A, the first intermediate arms 203AR and 203AL, and the first terminal arms 204AR and 204AL. Simultaneously, the second cross-connection point 206B moves backward by an interlock among the second driving arm 202B of the second substrate holding device 200B, the second intermediate arms 203BR and 203BL, and the second terminal arms 204BR and 204BL. Thus, the first substrate holder 205A extends, whereas the second substrate holder 205B retracts, while the first and second substrate holders 205A and 205B maintain the predetermined angle θ between them.

In contrast, as shown in FIGS. 7A to 7C, the first driving arm 202A is rotationally driven through a predetermined angle θ clockwise, and the second driving arm 202B is rotationally driven through the predetermined angle θ counterclockwise from the contraction state shown in FIGS. 5A to 5C. Then, the first cross-connection point 206A moves backward by an interlock among the first driving arm 202A of the first substrate holding device 200A, the first intermediate arms 203AR and 203AL, and the first terminal arms 204AR and 204AL. Simultaneously, the second cross-connection point 206B moves forward by an interlock among the second driving arm 202B of the second substrate holding device 200B, the second intermediate arms 203BR and 203BL, and the second terminal arms 204BR and 204BL. Thus, the first substrate holder 205A retracts, whereas the second substrate holder 205B extends, while the first and second substrate holders 205A and 205B maintain the predetermined angle θ between them.

<Guide Mechanism>

A guide mechanism will be described next with reference to FIGS. 8 to 10B.

FIG. 8 is an enlarged view of a portion P1 in FIG. 3, which shows a guide mechanism in a first example. A hole is formed in an axial end 110B of a second cross-connection point 106B to extend in the extension/contraction direction (Y direction), and the other end of a second guide bar 107B is axially supported in this hole via an elastomer bush 111B, as shown in FIG. 8. In this manner, a second support unit for the second guide bar 107B is formed at the second cross-connection point 106B, thereby supporting the second guide bar 107B in the hole to be slidable in the Y direction. Note that in the guide mechanism in the first example, the second guide bar 107B has a circular cross-sectional shape, and can rotate about its axis.

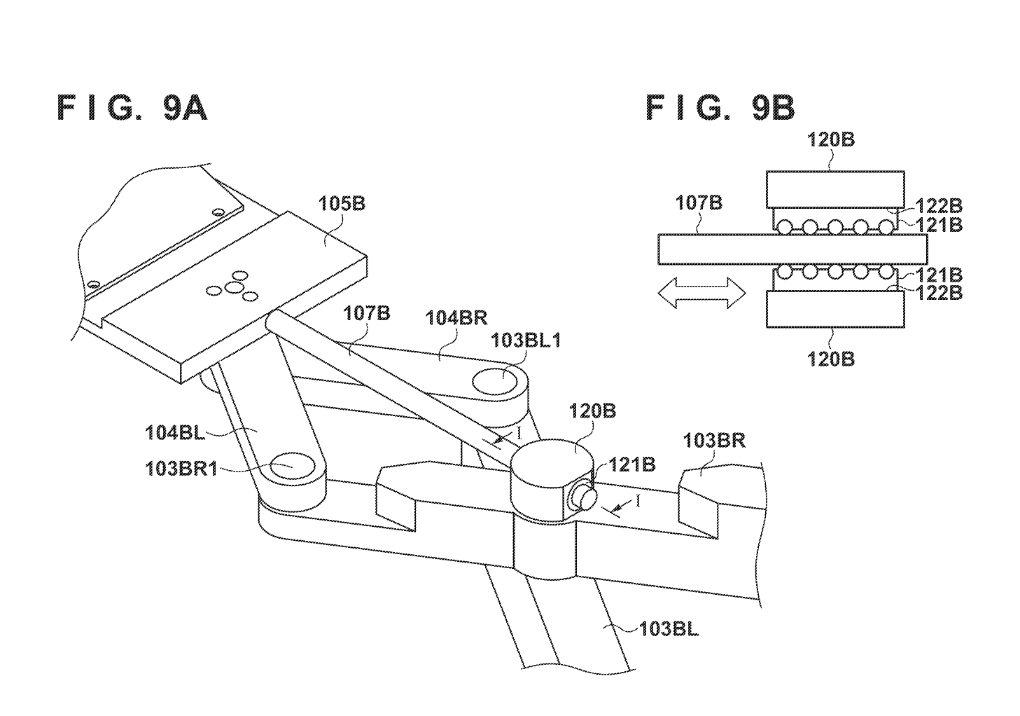

FIG. 9A is an enlarged view of the portion P1 in FIG. 3, which shows details of a guide mechanism in a second example, and FIG. 9B is a sectional view taken along a line I-I in FIG. 9A. A hole 122B is formed in an axial end 120B of the second cross-connection point 106B to extend in the extension/contraction direction (Y direction), and the other end of the second guide bar 107B is axially supported in the hole 122B via a bearing member 121B such as a ball bearing, as shown in FIGS. 9A and 9B. In this manner, a second support unit for the second guide bar 107B is formed at the second cross-connection point 106B, thereby supporting the second guide bar 107B in the hole 122B to be slidable in the Y direction. Note that in the guide mechanism in the second example, the second guide bar 107B has a circular cross-sectional shape, and does not rotate about its axis.

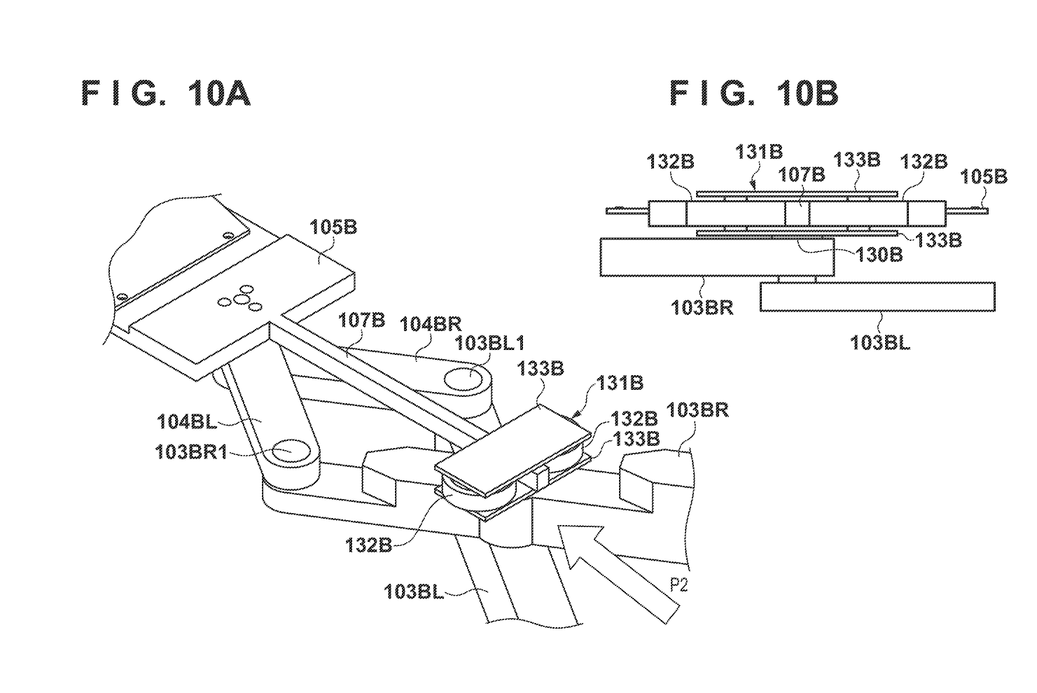

FIG. 10A is an enlarged view of the portion P1 in FIG. 3, which shows details of a guide mechanism in a third example, and FIG. 10A is a rear view of the guide mechanism in the third example when viewed from a direction indicated by an arrow P2 in FIG. 10A. A bearing member 131B including a pair of rollers 132B and a bearing case 133B which supports their roller axes is provided at an axial end 130B of the second cross-connection point 106B, thereby supporting the other end of the second guide bar 107B between the pair of rollers 132B, as shown in FIGS. 10A and 10B. In this manner, a second support unit for the second guide bar 107B is formed at the second cross-connection point 106B, thereby supporting the second guide bar 107B to be slidable in the extension/contraction direction (Y direction). Note that in the guide mechanism in the third example, the second guide bar 107B which abuts against the outer circumferential surfaces of the pair of rollers 132B has a rectangular cross-sectional shape (or a chamfered cross-sectional shape), and does not rotate about its axis.

Note that in the above-mentioned the first to third examples, for the first guide bar 107A of the first substrate holding device 100A as well, a first support unit is formed at the first cross-connection point 106A to support it.

Either of the above-mentioned guide mechanisms can rigidly control the behaviors of forks serving as substrate holders without using members such as gears having backlash or belts having elasticity.

Although an example in which the guide mechanisms are applied to the substrate transport apparatus (second substrate holding device 100B) in the first embodiment has been described herein, they are also applicable to the substrate transport apparatus in the second embodiment. Also, although an example in which one pair of rollers 132B are used has been described herein, pairs of rollers may be aligned on two or more lines. In this case, the rectilinear movement characteristics of the guide bar are expected to improve.

Moreover, although a configuration in which one end of the guide bar is attached to the substrate holder, and a support unit is provided at the cross-connection point between the intermediate arms to support the other end of the guide bar has been described in the above-mentioned example, a configuration in which the other end of the guide bar is attached to the cross-connection point, and a support unit is provided to the substrate holder to support one end of the guide bar may also be adopted. In summary, any configuration can be adopted as long as a guide bar is provided to one of the substrate holder and a link unit (the cross-connection point between the intermediate arms), and a support unit is provided to the other of the substrate holder and the link unit (the cross-connection point between the intermediate arms).

### Third Embodiment

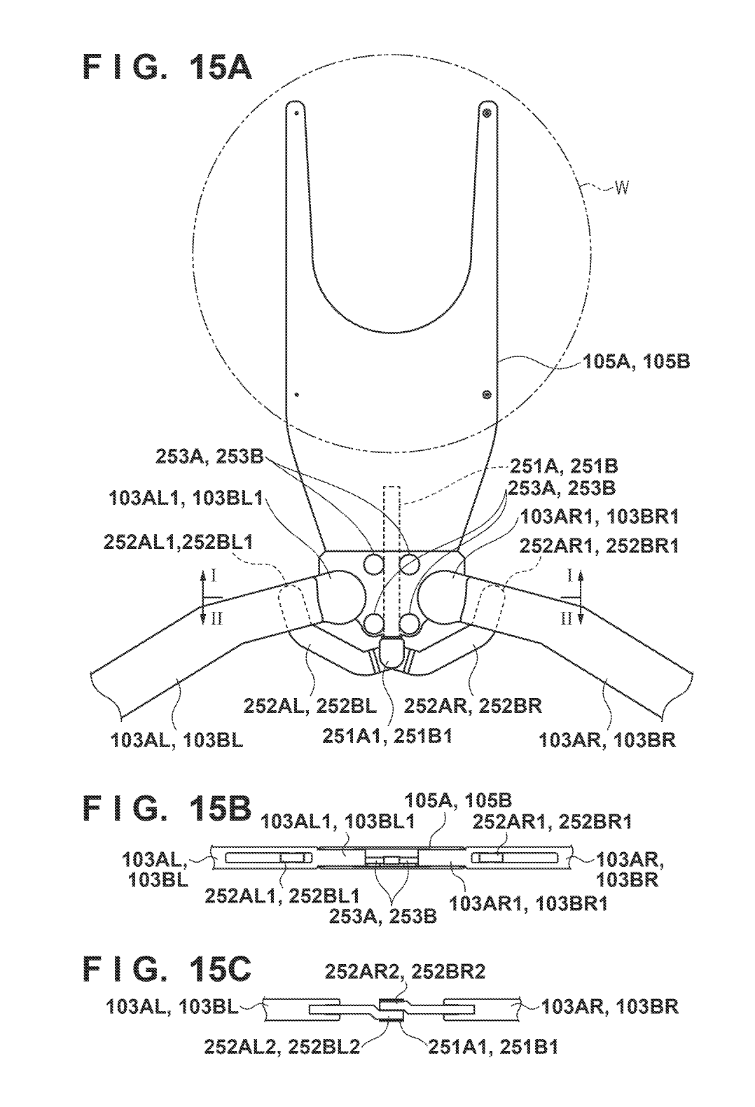

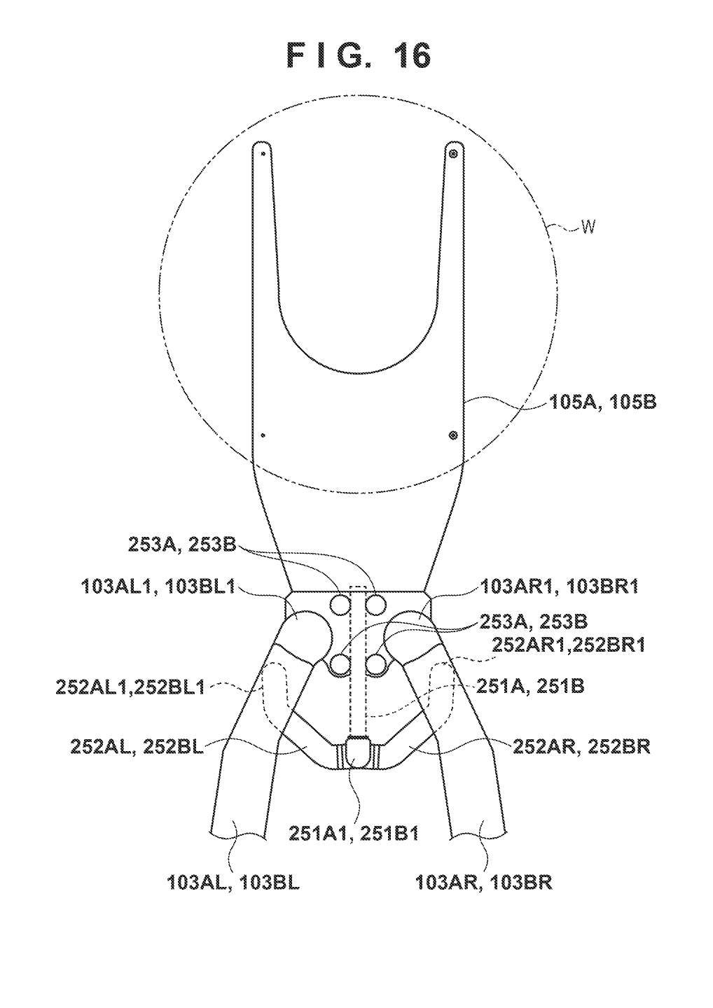

A substrate transport apparatus in the third embodiment according to the present invention will be described next with reference to FIGS. 15A to 16.

The substrate transport apparatus in this embodiment is different from that in the first embodiment in that in the former the first terminal arms 104AR and 104AL, second terminal arms 104BR and 104BL, first cross-connection point 106A, and second cross-connection point 106B are not used, but the other end 103AR1 of a first intermediate arm 103AR and the other end 103AL1 of a first intermediate arm 103AL in the pair of first intermediate arms 103AR and 103AL are connected to a first substrate holder 105A, and the other end 103BR1 of a second intermediate arm 103BR and the other end 103BL1 of a second intermediate arm 103BL in the pair of second intermediate arms 103BR and 103BL are similarly connected to a second substrate holder 105B. Again, in the former, first and second guide bars 251A and 251B are slidably supported by the rear ends of the first and second substrate holders 105A and 105B, respectively, to extend toward the arm distal ends (in the Y direction).

The first and second guide bars 251A and 251B have a rectangular cross-sectional shape, and are slidably supported by the proximal portions of the first and second substrate holders 105A and 105B, respectively, to which the first intermediate arms 103AR and 103AL and second intermediate arms 103BR and 103BL are connected, via a guide mechanism, as will be described later. Thus, oscillation of the first and second substrate holders 105A and 105B is suppressed in extending/contracting the first and second substrate holding devices 100A and 100B.

A pair of first link arms 252AR and 252AL are connected to the first intermediate arms 103AR and 103AL, respectively, in the vicinities of the other end 103AR1 of the first intermediate arm 103AR and the first intermediate arm 103AL of the first intermediate arm 103AL, respectively. Similarly, a pair of second link arms 252BR and 252BL is connected to the second intermediate arms 103BR and 103BL, respectively, in the vicinities of the other end 103BR1 of the second intermediate arm 103BR and the other end 103BL1 of the second intermediate arm 103BL, respectively.

One end 252AR1 of the first link arm 252AR and one end 252AL1 of the first link arm 252AL are connected to the first intermediate arms 103AR and 103AL, respectively, at positions a predetermined distance inside the other end 103AR1 of the first intermediate arm 103AR and the other end 103AL1 of the first intermediate arm 103AL, respectively. Similarly, one end 252BR1 of the second link arm 252BR and one end 252BL1 of the second link arm 252BL are connected to the second intermediate arms 103BR and 103BL, respectively, at positions the predetermined distance inside the other end 103BR1 of the second intermediate arm 103BR and the other end 103BL1 of the second intermediate arm 103BL, respectively.

On the other hand, both the other end 252AR2 of the first link arm 252AR and the other end 252AL2 of the first link arm 252AL are coaxially connected to a rear end 252A1 of the first guide bar 251A while being vertically stacked on each other. Similarly, both the other end 252BR2 of the second link arm 252BR and the other end 252BL2 of the second link arm 252BL are coaxially connected to a rear end 251B1 of the second guide bar 251B while being vertically stacked on each other.

A guide mechanism is formed by opposing two pairs of rollers 253A and 253B to each other in the X direction with a predetermined spacing between them in the Y direction, and guides so that the first and second guide bars 251A and 251B reciprocally operate in the Y direction by interlocking with the first and second intermediate arms 103AR, 103BR, 103AL, and 103BL.

In a contraction state shown in FIGS. 15A to 15C, the first and second intermediate arms 103AR, 103AL, 103BR, and 103BL make a maximum angle with each other. With this operation, the first and second link arms 252AR, 252AL, 252BR, and 252BL rotate in directions opposite to those in which the first and second intermediate arms 103AR, 103AL, 103BR, and 103BL, respectively, rotate, to pull the first and second substrate holders 105A and 105B to the direction coming out of the paper of FIGS. 15A to 15C while being guided by the first and second guide bars 251A and 251B. In this contraction state, as shown in FIG. 1A, a first driving arm 102A and second driving arm 102B, the first intermediate arm 103AR or 103AL and second intermediate arm 103BR or 103BL, and the first substrate holder 105A and second substrate holder 105B are vertically stacked on each other.

In this contraction state, the drive shafts of first and second driving units 101A and 101B are rotationally driven in the same direction. Thus, the first substrate holder 105A and second substrate holder 105B integrally swing (revolve) using the drive shafts of the first and second driving units 101A and 101B as common shafts.

On the other hand, the drive shafts of the first and second driving units 101A and 101B are rotationally driven in opposite directions from the contraction state shown in FIGS. 15A to 15C. Thus, the first substrate holder 105A and second substrate holder 105B extend/retract so as to extend/contract in opposite Y directions, and assume an extension/contraction state shown in FIG. 16.

In the extension/contraction state shown in FIG. 16, the first and second intermediate arms 103AR, 103AL, 103BR, and 103BL operate in opposite directions. With this operation, the first and second link arms 252AR, 252AL, 252BR, and 252BL rotate in directions opposite to those in which the first and second intermediate arms 103AR, 103AL, 103BR, and 103BL, respectively, rotate, to extend one of the first substrate holder 105A and second substrate holder 105B and retract the other while being guided by the first and second guide bars 251A and 251B (FIG. 1B).

Other configurations and operations are the same as in the first embodiment, and a description thereof will not be given. Also, the above-mentioned third embodiment is applicable not only to the first embodiment, in which the first and second driving arms 102A and 102B are stacked on each other in a contraction state, but also to the second embodiment, in which the first driving arm 202A and second driving arm 202B are disposed to have an offset between them in the Y direction (extension/contraction direction) in advance.

According to the third embodiment, compared to the first and second embodiments, the guide bars and guide mechanism can be reduced in thickness, thus shortening the vertical distance between the first substrate holder 105A and the second substrate holder 105B. This makes it possible to decrease the vertical stroke length during a substrate swapping operation. This, in turn, makes it possible to keep the height (volume) of a process chamber low, thus downsizing the apparatus.

<Control Block Configuration of Substrate Transport Apparatus>

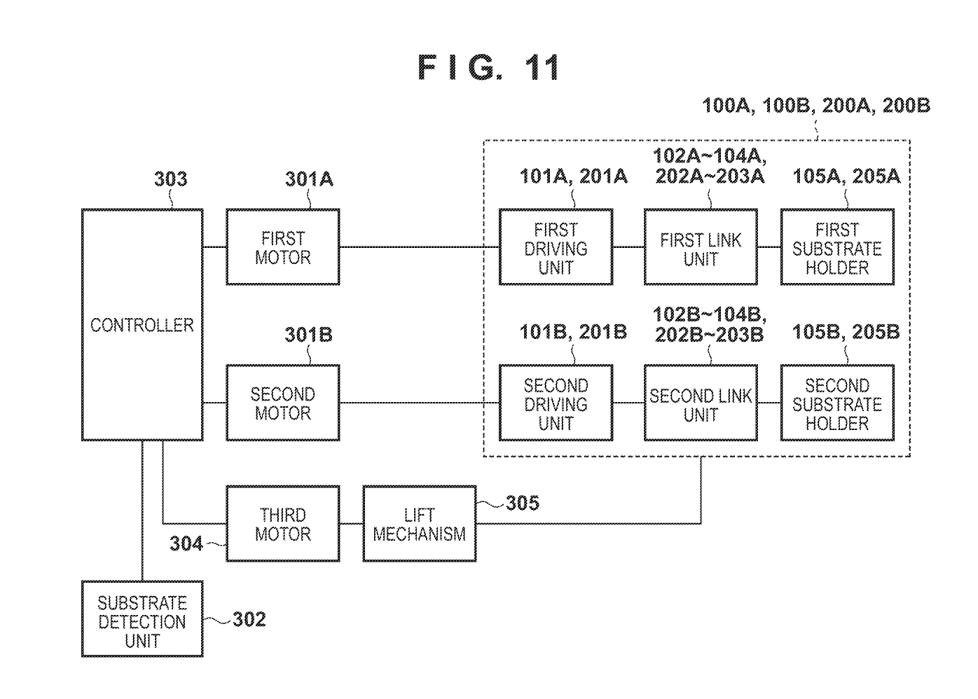

The control block configuration of a substrate transport apparatus according to an embodiment of the present invention will be described next with reference to FIG. 11. The first substrate holding device 100A or 200A includes a first motor 301A having an output shaft which applies a driving force to the first driving unit 101A or 201A. Similarly, the second substrate holding device 100B or 200B includes a second motor 301B having an output shaft which outputs a driving force to the second driving unit 101B or 201B. The rotational driving force of the first driving unit 201A disposed outside a vacuum chamber is transmitted to the first driving arm 102A or 202A via the first driving unit 101A or 201A. Similarly, the rotational driving force of the second motor 301B disposed outside the vacuum chamber is transmitted to the second driving arm 102B or 202B via the second driving unit 101B or 201B. A substrate detection unit 302 is disposed at a position vertically above or vertically below the first and second substrate holders 105A and 105B or 205A and 205B. The substrate detection unit 302 detects the positions of the first and second substrate holders 105A and 105B or 205A and 205B, and whether a substrate is held by at least one of the first and second substrate holders 105A and 105B or 205A and 205B. The detection result obtained by the substrate detection unit 302 is output to a controller 303.

The controller 303 controls the operations of the overall first and second substrate holding devices 100A and 100B or 200A and 200B based on pieces of detection information obtained by respective encoders provided in the first and second motors 301A and 301B, and the detection result obtained by the substrate detection unit 302.

The controller 303 synchronously controls the first motor 301A and second motor 301B so that the first and second substrate holders 105A and 105B or 205A and 205B synchronously rotate in the same direction.

Also, the controller 303 rotates the first and second substrate holding devices 100A and 100B or 200A and 200B relative to the substrate holding positions of process apparatuses to or from which a substrate is to be supplied or recovered, thereby positioning them at predetermined positions.

The rotational driving force of a third motor 304 disposed outside the vacuum chamber is transmitted to a lift mechanism 305, which lifts or lowers the first and second substrate holding devices 100A and 100B or 200A and 200B in the Z-axis direction.

The controller 303 controls the third motor 304 to control positioning, in the Z-axis direction, of the first substrate holder 105A or 205A and second substrate holder 105B or 205B relative to the substrate holding positions of process apparatuses to or from which a substrate is to be supplied or recovered.

In the above-mentioned configuration, by revolving, extending, and contracting the first and second substrate holding devices, the substrate transport apparatus can supply a substrate to each process apparatus or recover the processed substrate from the process apparatus.

<Operation of Substrate Transport Apparatus>

The operation of the substrate transport apparatus will be described next.

The controller 303 controls the revolution operation and extension/contraction operation of the substrate transport apparatus. More specifically, the swapping (supply/recovery) operation of a substrate with respect to each process apparatus, and the revolution operation of the substrate transport apparatus will be explained below assuming the situation in which an unprocessed substrate is placed on the first substrate holder 105A, whereas no substrate is placed on the second substrate holder 105B. Note that each process apparatus executes a predetermined process for the already supplied substrate.

(1) After completion of the process, the controller 303 revolves the first and second substrate holding devices 100A and 100B so that they are placed at positions at which the direction in which the second substrate holder 105B extends coincides with the substrate center in a process chamber of the process apparatus. At this time, the positions of the first and second substrate holders 105A and 105B in the height direction (Z direction) also move to those lower than the substrate level in the process chamber of the process apparatus.

(2) Then, the controller 303 sets the second substrate holding device 100B in an extension state to extend the second substrate holder 105B. When the second substrate holder 105B completes its extension operation, the substrate holding surface (fork) of the second substrate holder 105B is positioned below the lower surface of the substrate.

(3) The controller 303 lifts the second substrate holder 105B so that the position of the second substrate holder 105B in the height direction (Z direction) becomes higher than the substrate holding position of the process chamber, thereby picking up and placing the processed substrate on the substrate holding surface of the second substrate holder 105B.

(4) Then, the controller 303 sets the second substrate holding device 100B in a contraction state to retract the second substrate holder 105B. With this operation, recovery of the processed substrate from the process chamber of the process apparatus is completed.

(5) Next, the controller 303 revolves the first and second substrate holding devices 100A and 100B so that they are placed at positions at which the direction in which the first substrate holder 105A extends coincides with the substrate center in the process chamber of the process apparatus. At this time, the position of the first substrate holder 105A in the height direction (Z direction) moves to that lower than the level of the substrate holding position of the process chamber of the process apparatus.

(6) Then, the controller 303 sets the first substrate holding device 100A in an extension state to extend the first substrate holder 105A. When the first substrate holder 105A completes its extension operation, it is positioned above the substrate holding position of the process chamber.

(7) The controller 303 lowers the first substrate holder 105A so that the position of the first substrate holder 105A in the height direction (Z direction) becomes lower than the substrate holding position of the process chamber. In this way, the substrate held on the first substrate holder 105A is picked up and placed at the substrate holding position of the process chamber. In this state, the unprocessed substrate present on the first substrate holder 105A is placed at the substrate holding position of the process chamber.

(8) Finally, the controller 303 sets the first substrate holding device 100A in a contraction state to retract the first substrate holder 105A. With this operation, supply of an unprocessed substrate to be placed at the substrate holding position of the process chamber of the process apparatus is completed.

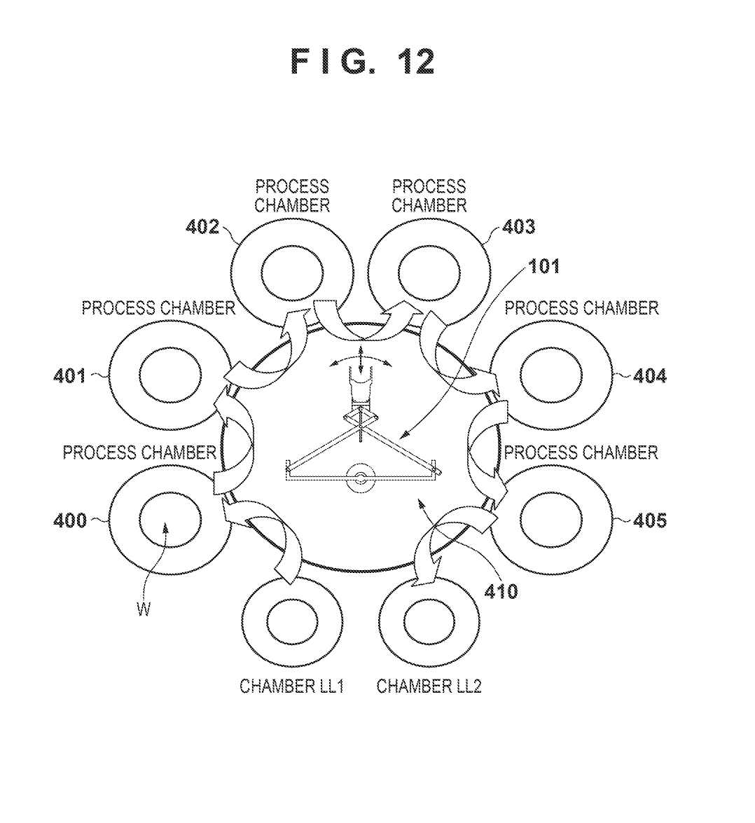

By executing the above-mentioned operations (1) to (8) for each process apparatus, the substrate transport apparatus can supply a substrate W to each of a plurality of process apparatuses (FIG. 12) arranged in a radial pattern. Alternatively, the substrate transport apparatus can recover the processed substrate from each process apparatus.

A case in which the substrate transport apparatus is used to transport a substrate into a chamber maintained at a high temperature, such as an annealing chamber or a process chamber that uses a high deposition temperature will be described herein. In this case, the substrate holders are moved into the chamber maintained at a high temperature. However, according to the configuration in the present invention, the support units for the guide bars are separated from the substrate holders toward the back (toward the drive axes), so a substrate can be transported without placing the substrate portions into the chamber having a high temperature. This produces an effect of suppressing degradation in operation reproducibility due to thermal expansion. Even if the support units are placed in the chamber having a high temperature, it is possible to shorten the time in which the holders and the guide bars are exposed to high temperatures, thus minimizing an adverse effect that thermal expansion exerts on the operation.

Although an example in which the above-mentioned operation is applied to the substrate transport apparatus in the first embodiment has been described herein, it is similarly applicable to the substrate transport apparatus in the second embodiment as well.

<Explanation of Effect>

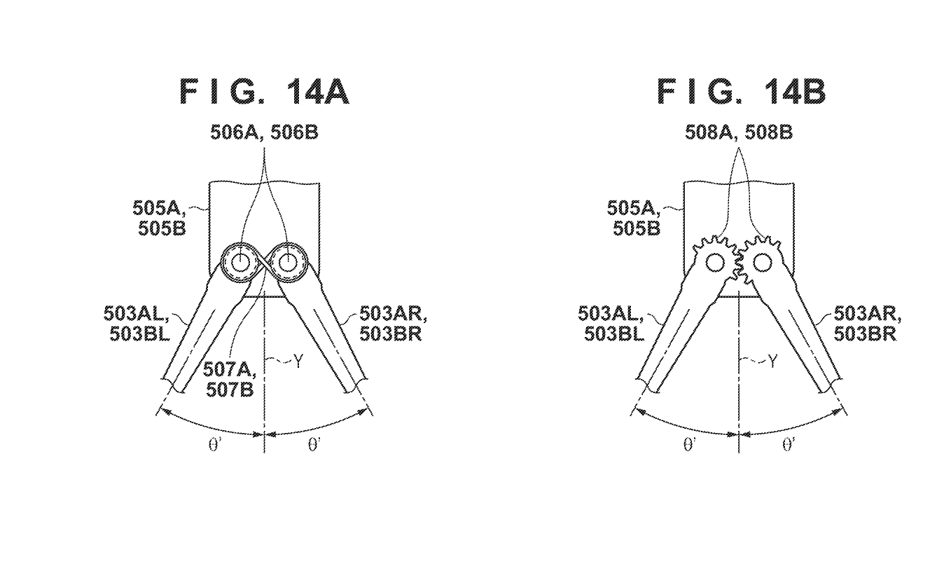

Referring to FIG. 14A, it is unavoidable to degrade the operation reproducibility (positioning reproducibility) due to elastic deformation of belts. Also, because of difficulty in tension adjustment mentioned above and because the behaviors of the forks cannot quickly be fed back due to the elasticity of belts while the behaviors of the distal ends of the forks are transmitted to the motors, the control response characteristics are degraded and the servo rigidity cannot be improved. On the other hand, referring to FIG. 14B, as backlash is present due to factors associated with gear meshing, the same problem is posed.

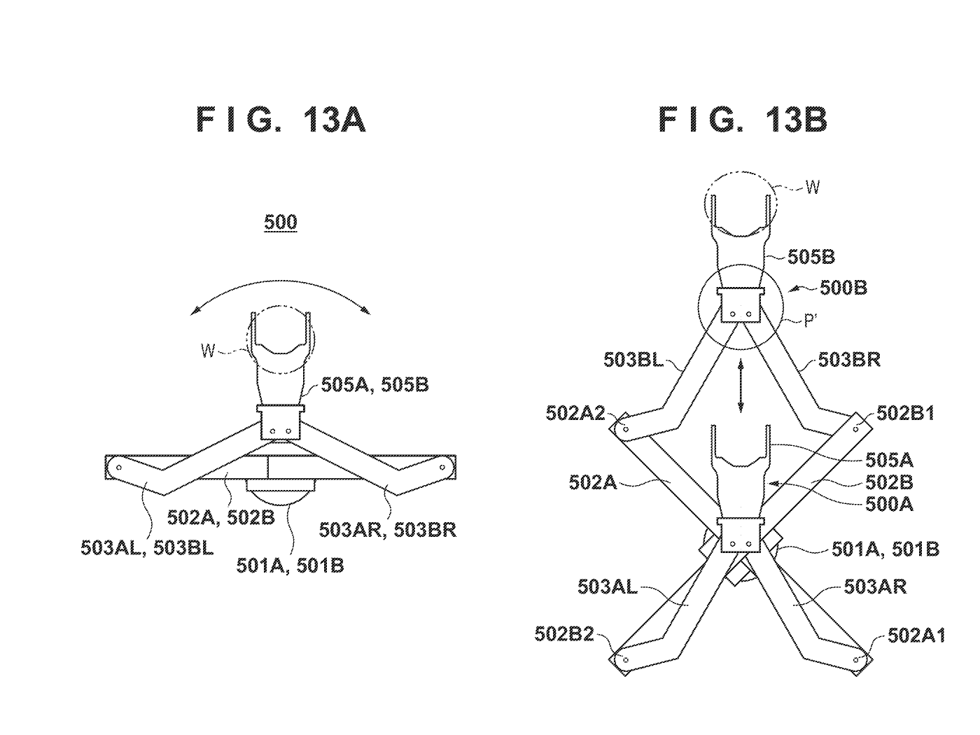

Furthermore, when the operations of the conventional arms shown in FIGS. 13A and 13B are observed in fine detail, because the pair of first intermediate arms 503AR and 503AL do not exhibit exactly the same behavior during extension/contraction operations, they may always perform yawing motions during the extension/contraction operations. For this reason, the substrate may slip and fall upon gaining an abrupt acceleration.

In contrast to this, this embodiment realizes a substrate transport apparatus capable of improving the operation reproducibility (positioning reproducibility), the control response characteristics, and the servo rigidity.

Also, since an increase in rigidity of a robot, a speedup of a response to feedback control, and a reduction in temporal change of components can be attained, stabilization and an improvement in reliability of a substrate transport system can be achieved, leading to an improvement in productivity.

Moreover, since the need for operations associated with belt adjustment and gear maintenance can be obviated, the operation efficiency can be improved. In each of the embodiments according to the present invention, since the support units are separated from the substrate holders toward the drive shafts, it is possible to avoid a decrease in strength due to thermal expansion and degradation in positioning accuracy even if a substrate is transported to an annealing chamber maintained at a high temperature.

Especially according to the second embodiment, it is possible not only to obtain the effect of the first embodiment but also to efficiently detect whether a substrate is held on each of a plurality of substrate holders. That is, it is possible to detect without using a member dedicated to sensor detection whether a substrate is held on each of a plurality of substrate holders from the vertically upward or vertically downward direction. This obviates the need for an expensive sensing technique, thus making it possible to reduce the cost of the entire apparatus. This also obviates the need to move the substrate holders forward and backward in order to detect a substrate, thus making it possible to shorten the take time of the apparatus.

<Electronic Device Manufacturing System and Method>

An electronic device manufacturing system and method will be described with reference to FIG. 12.

Load lock chambers LL1 and LL2 for loading/unloading a substrate W on which an electronic device is to be manufactured, and process chambers 400 to 405 for performing various processes on the substrate W, are arranged in a radial pattern around a transport chamber 410 in which the substrate transport apparatus 100 according to this embodiment is disposed. By arranging the process chambers 400 to 405 in a radial pattern around the substrate transport apparatus 100 in this way, one substrate transport apparatus 100 can transport a substrate to a plurality of process chambers 400 to 405. The electronic device manufacturing system according to this embodiment includes the substrate transport apparatus described in the above-mentioned embodiment, and at least one process apparatus which executes a device manufacturing process for a substrate transported by the substrate transport apparatus.

Although an example in which the above-mentioned electronic device manufacturing system is applied to the substrate transport apparatus 100 in the first embodiment has been described herein, it is similarly applicable to the substrate transport apparatus 200 in the second embodiment as well.

Also, the electronic device manufacturing method includes a transport step of transporting a substrate using a substrate transport apparatus, and a process execution step of executing a device manufacturing process for the substrate, transported in the transport step, using at least one process apparatus. An electronic device manufactured by the electronic device manufacturing system and electronic device manufacturing method includes, for example, at least one of a semiconductor, an LCD, a solar battery, and a device for an optical communication equipment.

According to this embodiment, it is possible to reduce the cost of the entire electronic device manufacturing system.

The present invention is not limited to the above-described embodiments, and can be changed and modified into various forms without departing from the spirit and scope of the present invention. Although, for example, a double-fork structure formed by a pair of a first substrate holding device and a second substrate holding device has been described in this embodiment, a single-fork structure formed by one of them may be adopted.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2010-242619, filed Oct. 28, 2010 and 2011-205215, filed Sep. 20, 2011, which are hereby incorporated by reference herein in their entireties.

What is claimed is:

1. A substrate transport apparatus comprising:
a substrate holder for holding a substrate;
a link portion which extends/retracts the substrate holder;
a driving unit which generates a driving force to operate the link portion;
a guide bar provided to one of the substrate holder and the link portion; and
a support portion which is provided to the other of the substrate holder and the link portion, and slidably supports the guide bar when the substrate holder moves by the operation of the link portion,
wherein the support portion is provided in the portion where a pair of intermediate arms of the link portion intersect with each other.

2. The apparatus according to claim 1, wherein the guide bar is provided to the substrate holder, and the support portion is provided to the link portion.

3. The apparatus according to claim 1, wherein the link portion comprises
a pair of driving arms connected to the driving unit;
wherein the pair of intermediate arms each have one end connected to a corresponding one of the pair of driving arms, and a portion on a side of the other end, which is connected to a portion on a side of the other end of the other intermediate arm so that the portions intersect with each other; and
a pair of terminal end arms each having one end connected to a corresponding one of the pair of intermediate arms, and the other end connected to the substrate holder.

4. The apparatus according to claim 1, wherein
the guide bar has a circular cross-sectional shape, and
the guide bar is supported via one of a bush and a ball-and-roller bearing provided in the support portion.

5. The apparatus according to claim 1, wherein
the guide bar has a rectangular cross-sectional shape, and
the guide bar is supported by a roller rotatably provided in the support portion.

6. A substrate transport apparatus comprising:
a first substrate holder and a second substrate holder for holding a substrate;
a first link portion and a second link portion which extend/retract the first substrate holder and the second substrate holder, respectively:
a first driving unit and a second driving unit which generate driving forces to operate said the first link portion and the second link portion, respectively;
a first guide bar provided to one of the first substrate holder and the first link portion;
a second guide bar provided to one of the second substrate holder and the second link portion;
a first support portion which is provided to the other of the first substrate holder and the first link portion, and slidably supports the first guide bar when the first substrate holder moves by the operation of the first link portion; and
a second support portion which is provided to the other of the second substrate holder and the second link portion, and slidably supports the second guide bar when the second substrate holder moves by the operation of the second link portion,
wherein the first support portion is provided in the portion where a pair of intermediate arms of the first link portion intersect with each other, and the second support portion is provided in the portion where a pair of intermediate arms of the second link portion intersect with each other.

7. The apparatus according to claim 6, wherein
the first link portion and the second link portion comprise
a first driving arm and a second driving arm connected to the first driving unit and the second driving unit, respectively;
wherein the pair of first intermediate arms each have one end connected to the first driving arm, and a portion on a side of the other end, which is connected to a portion on a side of the other end of the other first intermediate arm so that the portions intersect with each other, and the pair of second intermediate arms each have one end connected to the second driving arm, and a portion on a side of the other end, which is connected to a portion on a side of the other end of the other second intermediate arm so that the portions intersect with each other;
a pair of first terminal end arms each having one end connected to a corresponding one of the pair of first intermediate arms, and the other end connected to the first substrate holder; and
a pair of second terminal end arms each having one end connected to a corresponding one of the pair of second intermediate arms, and the other end connected to the second substrate holder.

8. The apparatus according to claim 6, wherein
the first guide bar and the second guide bar have a circular cross-sectional shape, and
the other end of the first guide bar is supported via one of a bush and a ball-and-roller bearing provided in the first support portion, and the other end of the second guide bar is supported via one of a bush and a ball-and-roller bearing provided in the second support portion.

9. The apparatus according to claim 6, wherein
the first guide bar and the second guide bar have a circular cross-sectional shape, and
the other end of the first guide bar is supported by a roller rotatably provided in the first support portion, and the other end of the second guide bar is supported by a roller rotatably provided in the second support portion.

10. The apparatus according to claim 6, wherein
the first link portion and the second link portion have
an extension state in which the second substrate holder is retracted when the first substrate holder is extended, while the second substrate holder is extended when the first substrate holder is retracted, and
a contraction state in which both the first substrate holder and the second substrate holder are retracted and stacked on each other.

11. The apparatus according to claim 6, wherein
the first link portion and the second link portion have
an extension state in which the second substrate holder is retracted when the first substrate holder is extended, while the second substrate holder is extended when the first substrate holder is retracted, and
a contraction state in which both the first substrate holder and the second substrate holder are retracted to make a predetermined angle with each other.

12. The apparatus according to claim 10, wherein when the first link portion and the second link portion are in the contraction state, the first substrate holder and the second substrate holder swing using drive shafts of the first driving unit and the second driving unit as centers while maintaining a predetermined angle therebetween.

13. An electronic device manufacturing system comprising:
the substrate transport apparatus according to claim 1; and
at least one process apparatus which executes a device manufacturing process for a substrate transported by the substrate transport apparatus.

14. An electronic device manufacturing system comprising:
the substrate transport apparatus according to claim 6; and
at least one process apparatus which executes a device manufacturing process for a substrate transported by the substrate transport apparatus.

15. An electronic device manufacturing method comprising the steps of:
transporting a substrate using a substrate transport apparatus defined in claim 1; and
executing a device manufacturing process for the substrate, transported in the transporting step, using at least one process apparatus.

16. An electronic device manufacturing method comprising the steps of:
transporting a substrate using a substrate transport apparatus defined in claim 6; and
executing a device manufacturing process for the substrate, transported in the transporting step, using at least one process apparatus.
